(19) United States
(12) Patent Application Publication
(10) Pub. No.: US 2024/0313088 A1
(43) Pub. Date: Sep. 19, 2024

(54) INTEGRATED SEMICONDUCTOR STRUCTURE AND METHOD FOR MAKING THE SAME

(71) Applicant: XIAMEN SAN'AN INTEGRATED CIRCUIT CO., LTD., Xiamen (CN)

(72) Inventors: Shenghou LIU, Xiamen (CN); Wenbi CAI, Xiamen (CN); Boting LIU, Xiamen (CN); Xiguo SUN, Xiamen (CN)

(21) Appl. No.: 18/675,722

(22) Filed: May 28, 2024

Related U.S. Application Data
(63) Continuation-in-part of application No. PCT/CN2022/118855, filed on Sep. 15, 2022.

(30) Foreign Application Priority Data
Dec. 13, 2021 (CN) 202111523067.X

(51) Int. Cl. H01L 29/66; H01L 27/092; H01L 29/20; H01L 29/778

(52) U.S. Cl. CPC H01L 29/66462; H01L 27/092; H01L 29/2003; H01L 29/7786

(57) ABSTRACT

An integrated semiconductor structure includes a silicon substrate, a silicon-based semiconductor device, and a nitride-based semiconductor device. The silicon substrate has a first area and a second area. The first area is formed with a trench that has a trench surface with a (111) orientation. The second area has an area surface with a (100) orientation. The silicon-based semiconductor device is disposed on the area surface with the (100) orientation. The nitride-based semiconductor device is disposed on the trench surface with the (111) orientation. A method for making the integrated semiconductor structure includes: a) providing a silicon substrate having first and second areas each having an area surface; b) forming a silicon-based semiconductor device on the area surface of the second area; c) wet etching the first area to form a trench having a trench surface; and d) forming a nitride-based semiconductor device on the trench surface.

### CROSS-REFERENCE TO RELATED APPLICATION

This application is a continuation-in-part (CIP) of International Application No. PCT/CN2022/118855, filed on Sep. 15, 2022, which claims priority to Chinese Invention patent application Ser. No. 20/211,1523067.X, filed on Dec. 13, 2021, and incorporated by reference herein in its entirety.

### FIELD

The disclosure relates to an integrated semiconductor structure, and more particularly to an integrated semiconductor structure and a method for making the integrated semiconductor structure.

### BACKGROUND

Two dimensional electron gas (2DEG) formed from nitride semiconductor heterojunctions has advantages such as high electron density and high electrode mobility, and has therefore found wide application in various fields. Currently nitride-based semiconductor materials are mostly grown on silicon carbide or sapphire substrates.

Silicon is an important semiconductor material that is already widely used in silicon-based semiconductor devices (e.g., complementary metal-oxide-semiconductor (CMOS) devices). However, because the crystal orientation of a substrate required for growing nitride-based semiconductor devices is different from that required to grow silicon-based semiconductor devices, it is difficult to integrate silicon-based semiconductor devices with nitride-based semiconductor devices the substrate.

More specifically, silicon materials are often used for preparing a silicon substrate that is used for supporting various semiconductors devices and integrated circuits. However, the silicon substrate usually has a (100) crystal orientation which has good lattice matching with the silicon-based semiconductor devices, but unfavorable lattice matching characteristics with nitride-based heterojunctions. Therefore epitaxially growing nitride-based heterojunctions on the silicon substrate with (100) orientation may result in nitride-based heterojunctions of lesser quality that may not fulfil user requirements, and restrict the integration of silicon-based semiconductor devices with nitride-based semiconductor devices on the silicon substrate.

### SUMMARY

Therefore, an object of the disclosure is to provide an integrated semiconductor structure and a method for making the integrated semiconductor structure that can alleviate at least one of the drawbacks of the prior art.

According to one aspect of the disclosure, the integrated semiconductor structure includes a silicon substrate, a silicon-based semiconductor device, and a nitride-based semiconductor device. The silicon substrate has a first area, and a second area. The first area is formed with a trench that has a trench surface with a (111) orientation. The second area has an area surface with a (100) orientation. The silicon-based semiconductor device is disposed on the area surface with the (100) orientation of the second area. The nitride-based semiconductor device is disposed on the trench surface with the (111) orientation of the trench.

According to another aspect of the disclosure, a method for making the integrated semiconductor structure includes steps of: a) providing a silicon substrate having a first area and a second area each having an area surface with a (100) orientation; b) forming a silicon-based semiconductor device on the area surface with the (100) orientation of the second area (B) of the semiconductor substrate; c) wet etching the first area of the silicon substrate to form a trench having a trench surface with a (111) orientation; and d) forming a nitride-based semiconductor device on the trench surface to create a device preform.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating steps in an embodiments of a method of making an integrated semiconductor device according to the present disclosure.

FIGS. 2 to 16 are schematic cross-sectional and schematic top views illustrating the integrated semiconductor device in various stages of being made according to the method of the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 9, an embodiment of an integrated semiconductor structure according to the present disclosure includes a silicon 10 substrate 210, a silicon-based semiconductor device 300, and a nitride based semiconductor device 400. The silicon substrate 210 has a first area (A), and a second area (B). The first area (A) is formed with a trench (V) that has a trench surface with a (111) orientation. It should be noted that the first area (A) undergoes crystal orientation treatment to change the orientation of the first area (A) from a 15 (100) orientation to the (111) orientation.

The nitride-based semiconductor device 400 is disposed on the trench surface with the (111) orientation, of the trench (V). The second area (B) has an area surface with a (100) orientation. The silicon-based semiconductor device 300 is disposed on the area surface with the (100) orientation, of the second area (B). Since silicon-based devices have good lattice matching characteristics with (100) crystal orientation, the silicon-based semiconductor device 300 that is formed on the second area (B) of the silicon substrate 210 may be of a higher quality.

As shown in FIG. 9, the nitride-based semiconductor device 400 includes a nucleation layer 230, a nitride-based heterojunction 240, and an electrode structure. The nucleation layer 230 is disposed in and fills the trench (V), and is formed with a flat surface. The nitride-based heterojunction 240 is disposed on the flat surface of the nucleation layer 230. The electrode structure is disposed on the nitride-based heterojunction 240. More specifically, the nucleation layer 230 is epitaxially grown on the trench surface with the (111) crystal orientation, of the trench (V). In some embodiments, the nucleation layer 230 has a thickness that ranges from 20 nm to 100 nm, and is made of a group III-V compound semiconductor material. The epitaxial growth of the nucleation layer 230 is volumetric and fills the trench (V) formed with the flat surface. With the nucleation layer 230 formed with the flat surface, the nitride-based heterojunction 240 (e.g., GaN heterojunction that may be epitaxially grown on the flat surface of the nucleation layer 230 in a later process, may be grown planarly and be of a higher quality. If the trench (V) is made too deep, the nitride-based heterojunction 240 may grow volumetrically which will result in the nitride-based heterojunction 240 being of a worse quality. In some embodiments, the nucleation layer 230 may be made of AlN. Since the nucleation layer 230 has good lattice matching characteristics with the (111) crystal orientation, the nucleation layer 230 will be formed with a higher quality. Additionally, the nitride-based heterojunction 240 is epitaxially grown on the flat surface of the nucleation layer 230. Since the nitride-based heterojunction 240 has better lattice matching characteristics with the nucleation layer 230, the nitride-based heterojunction 240 thus formed will be of a higher quality.

In summary of the disclosure thus far, the silicon-based semiconductor device 300 and the nitride-based semiconductor device 400 require surfaces with different crystal orientations ((100) or (111)) to achieve optimal epitaxial growth. Therefore, crystal orientation treatment is performed on the first area (A) while the second area (B) is left untreated. This allows the silicon substrate (210) to simultaneously have the second area (B) with the (100) orientation and the first area (A) with the (111) orientation, and to have the silicon-based semiconductor device 300 grown on the second area (B) and the nitride-based semiconductor device 400 grown on the first area (A) to both be of a higher quality. Additionally, with the above design, the nitride-based semiconductor device 400 having the nitride-based heterojunction 240 may be well integrated with the silicon-based semiconductor device 300 on the silicon substrate 210. In some embodiments, the silicon substrate 210 may be a high resistance substrate, an N-type conductive substrate, or a P-type conductive substrate etc.

Referring to FIG. 9, in some embodiments, the electrode structure disposed on the nitride-based heterojunction 240 may include a source electrode (S), a drain electrode (D), and a gate electrode (G). The source electrode (S) and the drain electrode (D) may form ohmic contacts with the nitride-based heterojunction 240, and the gate electrode (G) may from a Schottky contact with the nitride-based heterojunction 240. The gate electrode (G) may be a t-shaped gate electrode for better efficiency.

Referring to FIG. 9, in some embodiments, a thickness of the nucleation layer 230 is no less than a trench depth (h) of the trench (V). This is so that the nucleation layer 230 is thick enough to cover the trench (V), which allows the nucleation layer 230 to be disposed in and fill the trench (V) and formed with the flat surface, thereby providing a flatter surface for the epitaxial growth of the nitride-based heterojunction 240. The nitride-based heterojunction 240 thus formed would be of a higher quality. In some embodiments, the nucleation layer 230 may be a III-V compound semiconductor material that has better lattice matching characteristics with the (111) orientation of the silicon substrate 210 than the (100) orientation.

In some embodiments, the silicon-based semiconductor device 300 may include discrete devices or circuit structures. The semiconductor components may, for example, be a diode, or a triode. The circuit structures may be digital circuits or analogue circuits. The silicon-based semiconductor device 300 includes a well region 301 formed in the silicon substrate 210 via ion implantation, and a first doped area and a second doped area that are formed in the well region 301 and are spaced apart from each other. A dielectric layer 302 is formed on the silicon substrate 210 and between the first doped area and the second doped area, and a gate electrode (G) is formed on the dielectric layer. In this embodiment, the first doped area may be a source electrode (S), and the second doped area may be a drain electrode (D). It should be noted that, the well region 301 may be doped with a different type of dopant compared to the first doped area and the second doped area. For example the well region 301 may be doped with an N-type dopant, while the first doped area and the second doped area are doped with a P-type dopant. In some embodiments, the well region 301 may be doped with a P-type dopant, while the first doped area and the second doped area are doped with an N-type dopant.

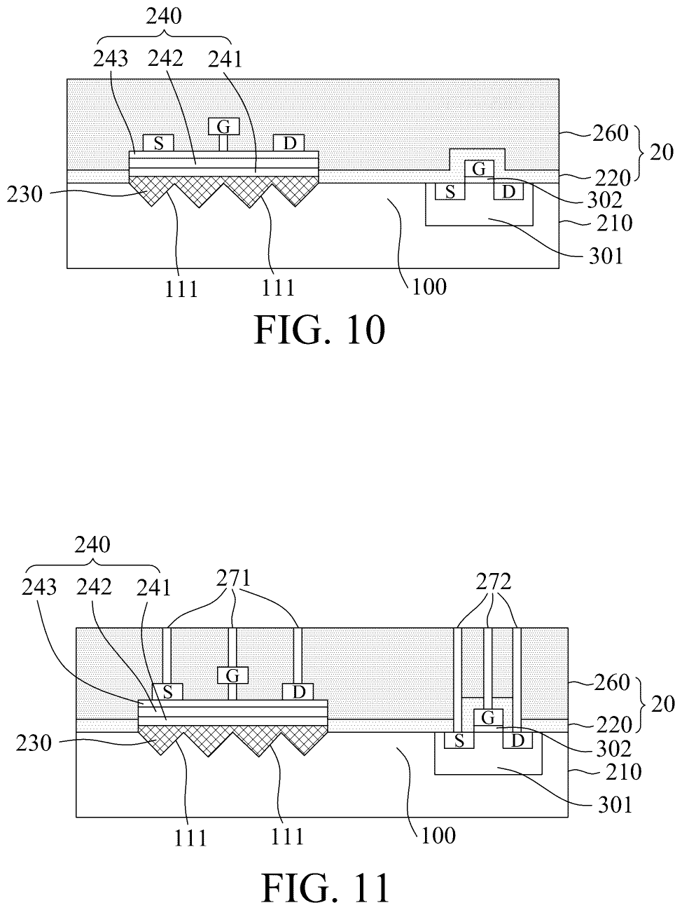

Referring to FIGS. 10 to 12, the integrated semiconductor device may further include a protection layer 20 covering the silicon-based semiconductor device 300 and the nitride-based semiconductor device 400 on the silicon substrate 210. The protection layer 20 isolates the silicon-based semiconductor device 300 from the nitride-based semiconductor device 400 and forms passivation protection for the silicon-based semiconductor device 300 and the nitride-based semiconductor device 400, thereby preventing the intrusion of moisture.

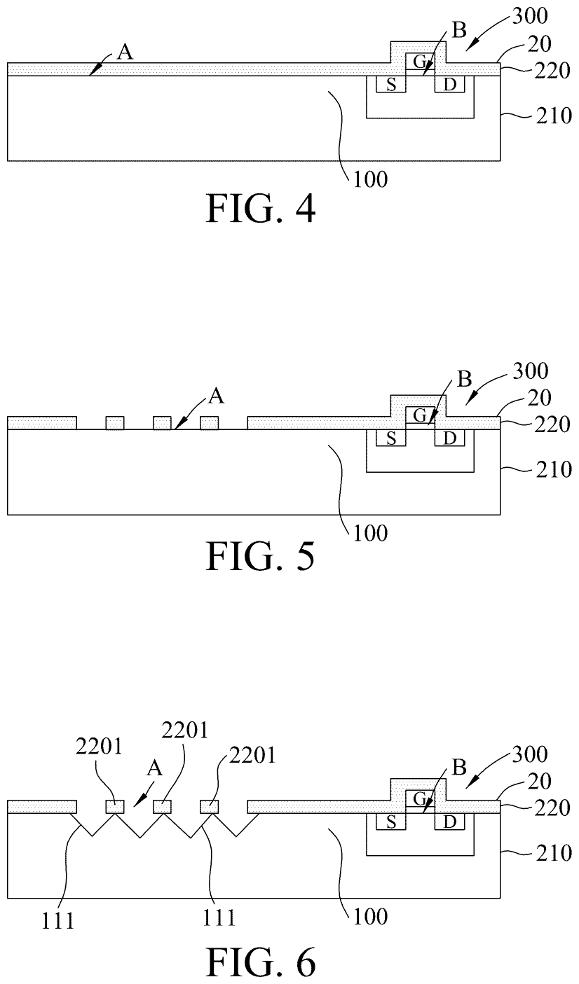

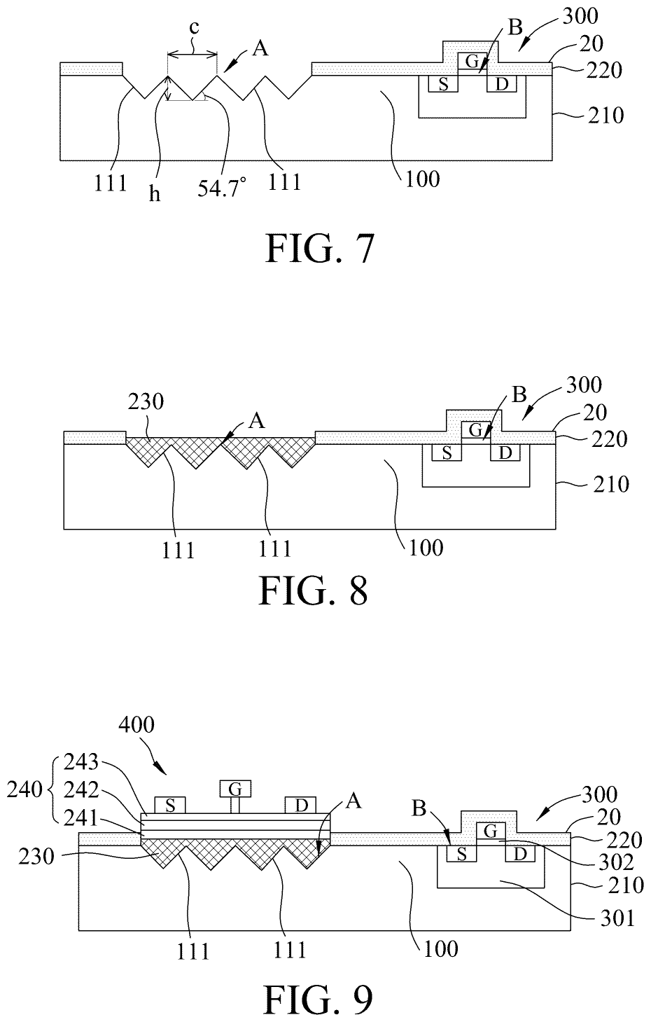

Referring to FIGS. 10 to 12, the protection layer 20 includes an insulating layer 220, and a passivation layer 260. Referring to FIGS. 3 and 4, the insulating layer 220 covers the silicon-based semiconductor device 300 and the silicon substrate 210. This allows the silicon-based semiconductor device 300 to be isolated from the nitride-based semiconductor device 400 when forming the nitride-based semiconductor device 400 in the trench (V) in the first area (A) of the silicon substrate 210, and prevents damaging the silicon-based semiconductor device 300. Referring to FIGS. 5 and 6, the insulating layer 220 may be used as a mask layer during formation of the trench (V) in the first area (A) of the silicon substrate 210. Referring to FIGS. 7 to 9, after forming the trench (V), the insulating layer 220 in the first area (A) over the trench (V) is removed so that the insulating layer 220 covers the silicon-based semiconductor device 300 and the silicon substrate 210 excepting the first area (A). In this way, the silicon-based semiconductor device 300 and the nitride-based semiconductor device 400 are well isolated and electrically insulated from each other. In some embodiments, the insulating layer 220 is made of silicon oxide.

Referring to FIGS. 9 and 10, the passivation layer 260 may be formed after the nitride-based semiconductor device 400 is formed to cover the insulating layer 220 and the nitride-based semiconductor device 400 respectively in the second area (B) and the first area (A) of the silicon substrate 210. That is, the passivation layer 260 covers the insulating layer 220 and the nitride-based semiconductor device 400 after the insulating layer 220 and the nitride based semiconductor device 400 have been formed. The passivation layer 260 forms passivation protection for components underneath and prevents the intrusion of moisture.

In some embodiments, the protection layer 20 may be planarized to have a flat upper surface. This provides better continuity and reliability when laying circuitry with metal wires. A top layer of the protection layer 20 is the passivation layer 260. The passivation layer 260 may be made of a dielectric material or an organic insulation material. When the passivation layer 260 is made of the dielectric material such as silicon oxide, silicon nitride, aluminum oxide, and silicon oxynitride, the passivation layer 260 may be formed via a deposition process such as plasma-enhanced chemical vapor deposition (PECVD), low pressure chemical vapor deposition (LPCVD), or sputtering. The passivation layer 260 may then be palanarized via chemical-mechanical polishing to have the flat upper surface. On the other hand, when the passivation layer 260 is made of the organic insulation material, the passivation layer 260 be spin coated to have the flat upper surface.

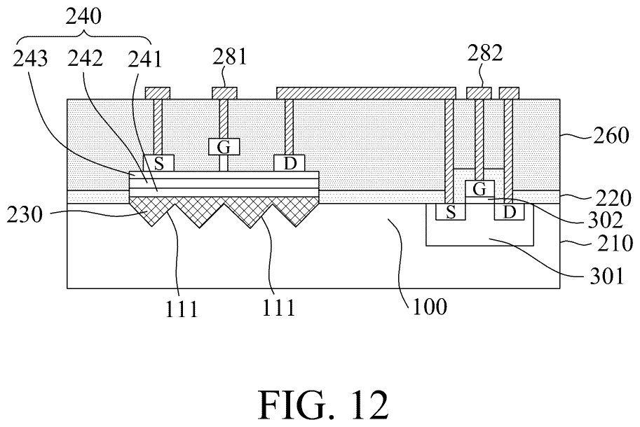

Referring to FIG. 12, the integrated semiconductor structure further includes a first interconnecting metallic structure 281, and a second interconnecting metallic structure 282. The first and second interconnecting metallic structures 281, 282 are formed after epitaxially growing the silicon-based semiconductor device 300 and the nitride-based semiconductor device 400 to electrically connect the silicon-based semiconductor 300 with the nitride-based semiconductor device 400. The first interconnecting metallic structure 281 extends from the flat upper surface of the protection layer 20 through the protection layer 20 to the nitride-based semiconductor device 400 to be electrically connected with the electrode structure of the nitride-based semiconductor device 400. The second interconnecting metallic structure 282 extends from the flat upper surface of the protection layer 20 through the protection layer 20 to the silicon-based semiconductor device 300 to be electrically connected with the silicon-based semiconductor device 300. The first interconnecting metallic structure 281 may be electrically connected with the second interconnecting metallic structure 282 at the flat upper surface of the protection layer 20.

Referring to FIG. 8, in some embodiments, the integrated semiconductor structure includes a plurality of the trenches (V) formed contiguously in the first area (A). In these embodiments, when the nucleation layer 230 of the nitride-based semiconductor device 400 is epitaxially grown on the trench surface with the (111) crystal orientation, of the trenches (V), a plurality of island shaped nucleation seeds may be discretely deposited in the trenches (V) that will three-dimensionally grow to fill the trenches (V) and form the nucleation layer 230 with the flat surface.

Referring to FIG. 7, in some embodiments, the integrated semiconductor structure includes a plurality of trenches (V) and each of the trenches (V) has a trench depth (h) and an opening that has a width (c). The trench surface of each of the trenches (V) is inclined with respect to a horizontal reference plane at an inclined angle (α). In this embodiment, the relation between the trench depth (h), the width (c) and the inclined angle (α) is described by c/h=1/(2 tan(α)). Here, the inclined angle (α) ranges from 54.5° to 54.9°, and the trench depth (h) ranges from 20 nm to 100 nm. In some embodiments, the width (c) of the opening is 1.43 times the trench depth (h), and the inclined angle (α) is 54.7°. In this way, the trenches (V) are shallower, which is conducive to epitaxially growing the nucleation layer 230 so that the nucleation layer 230 is disposed in and fills the trenches (V) and formed with the flat surface.

Referring to FIGS. 7 and 8, in some embodiments, the trench depth (h) may be less than 100 nm. In this way, the epitaxially grown nucleation layer 230 may fill the trenches (V) completely.

Referring to FIG. 9, in some embodiments, the nitride-based heterojunction 240 includes a buffer layer 241, a channel layer 242, and a barrier layer 243 that are sequentially grown on the flat surface of the nucleation layer 230, and that are basic structural elements of a nitride-based semiconductor device having high electron mobility. It should be noted that the buffer layer 241, the channel layer 242, and the barrier layer 243 may each be made of a III-V compound semiconductor material. The buffer layer 241 and the channel layer 242 may each be a binary compound or a ternary compound, and the barrier layer 243 may be a ternary compound or a quaternary compound. In some embodiment, the buffer layer 241 and the channel layer 242 may be made of the same material, for example, GaN which would simplify the epitaxial growth procedure.

In some embodiments, the buffer layer 241 may be made of one of GaN and AlₓGa₁₋ₓN. The buffer layer 241 may be doped with Fe, C, O or undoped.

In some embodiments, the buffer layer 241 may have a thickness that ranges from 20 nm to 8 μm. The thickness of the buffer layer 241 may be designed according to practical requirements.

In some embodiments, the channel layer 242 is made of one of GaN and AlₓGa₁₋ₓN. The channel layer 242 may be doped with Fe, C, O etc, or be unintentionally doped.

In some embodiments, the channel layer 242 has a thickness that ranges from 10 nm to 200 nm; the thickness of the channel layer 242 may be designed according to practical requirements.

In some embodiments, the barrier layer 243 is made of one of AlN, InN, AlₓGa₁₋ₓN, InₓAl₁₋ₓN, InₓAl_{y}GaN.

In some embodiments, the barrier layer 243 has a thickness that ranges from 1 nm to 50 nm; the thickness of the barrier layer 243 may be designed according to practical requirements.

In some embodiments, the nucleation layer 230 is made of AlN.

In some embodiments, the nucleation layer 230 has a thickness that ranges from 10 nm to 100 nm; the thickness of the nucleation layer 230 may be designed according to practical requirements. It should be noted that, due to the consideration of obtaining the flat surface of the nucleation layer 230, the nucleation layer 230 should have a thickness that is greater than the trench depth (h) of the trench (V) so that the nucleation layer 230 may completely fill in the trench (V).

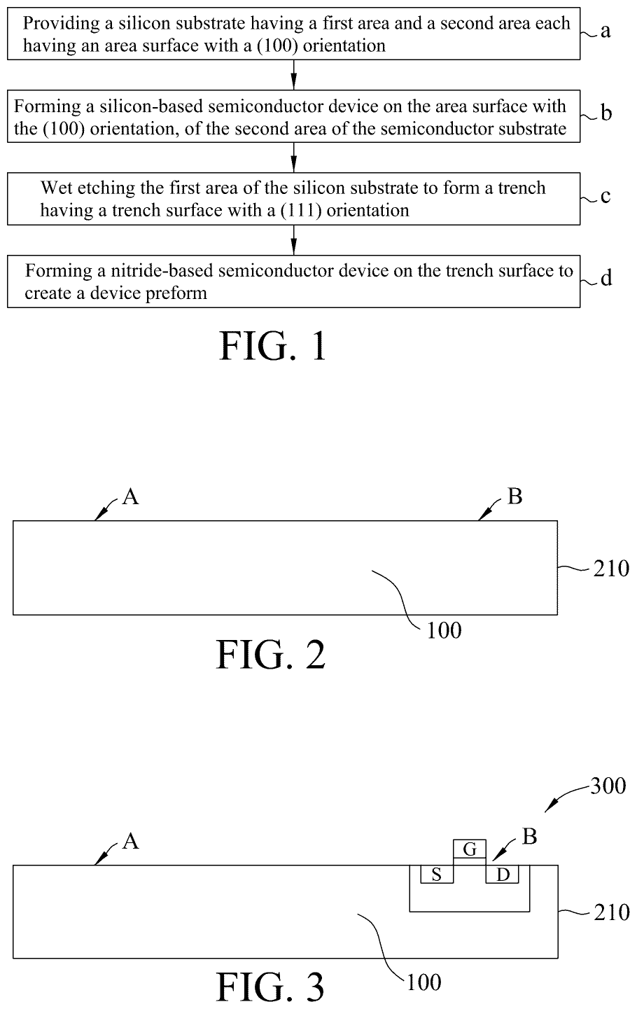

Referring to FIG. 1, an embodiment of a method for making the integrated semiconductor structure according to the present disclosure includes steps a) to d). In the step a), the silicon substrate 210 is provided. The silicon substrate 210 has the first area (A) and the second area (B) each having an area surface with a (100) orientation.

Referring to FIG. 2, in some embodiments, the silicon substrate 210 may be a high resistance substrate, an N-type conductive substrate, or a P-type conductive substrate etc.

Referring to FIG. 3, in the step b), the silicon-based semiconductor device 300 is formed on the area surface with the (100) orientation, of the second area (B) of the silicon substrate 210.

Since the silicon-based device 300 may have good lattice matching characteristics with the (100) crystal orientation on the area surface of the second area (B), the silicon-based semiconductor device 300 thus formed will be of a superior quality.

In the step c), the first area (A) of the silicon substrate (210) which is with the (100) orientation is wet etched to from the trench (V). The trench (V) has a trench surface with the (111) orientation.

The wet etching may use a base liquid as an etchant such as potassium hydroxide (KOH) or tetramethylammonium hydroxide (TMAH). The wet etchant used has a higher etch rate selectivity for the (100) orientation than the (111) orientation. Therefore, wet etching the silicon substrate 210 has the effect of etching away the area surface with the (100) orientation and forming the trench (V) having the trench surface with the (111) orientation. Referring to FIG. 7, in some embodiments a plurality of trenches (V) are formed via the wet etching in step c).

In the step d), the nitride-based semiconductor device 400 is formed on the trench surface of the trench (V) to create a device preform as shown in FIG. 9.

In summary of the above so far, since the nitride-based semiconductor device 400 and the silicon-based semiconductor device 300 are each more suitable to be grown on areas of silicon substrates 210 with different crystal orientations, the integrated semiconductor structure made according to this embodiment will have both the (111) orientation and the (100) orientation on different areas of the silicon substrate 210. More specifically, the area surface with (100) orientation of the first area (A) of the silicon substrate 210 is wet etched to form the trench (V) having the trench surface with the (111) orientation, while the second area (B) of the silicon substrate 210 continues to have the area surface with the (100) orientation. In this way, the silicon-based semiconductor device 300 and the nitride-based semiconductor device 400 may each be formed with a higher quality.

Referring to FIG. 4, the step c) of wet etching the first area (A) may include steps c1) to c3). In the step c1), an insulating layer 220 is formed on the silicon substrate 210 to cover the first area (A), and the silicon-based semiconductor device 300 on the second area (B). Referring to FIG. 5, in the step c2), the insulating layer 220 is patterned to expose the first area (A) of the silicon substrate 210. In this embodiment, the insulating layer 220 is patterned via photolithography to have a covering portion that partially covers the first area (A) and a recessed portion from which the area surface of the first area (A) is exposed. Referring to FIG. 6, in the step c3), the exposed first area (A) of the silicon substrate 210 is wet etched to form the trench (V) having the trench surface with the (111) orientation. The etchant etches the exposed first area (A) and stops at a (111) orientation of the silicon substrate 210 due to a higher atomic density of the (111) orientation (also due to the etch selectivity of the etchant). In this way, the trench (V) having the trench surface with the (111) orientation is formed. After performing the step c3), the covering portion of the insulating layer 220 that partially covers the first area (A) is removed and a device as shown in FIG. 7 is obtained. The insulating layer 220 offers the advantage of protecting and isolating the silicon-based semiconductor device 300 when wet etching the first area (A) to form the trench (V) and forming the nitride-based semiconductor device 400 to prevent damaging the silicon-based semiconductor device 300. Additionally, referring to FIGS. 5 and 6, it should be noted that the insulating layer 220 may be used as an etching mask when wet etching the first area (A) of the silicon substrate 210. Referring to FIGS. 7 to 9, the insulating layer 220 above the first area (A) is removed so that the insulating layer 220 covers the silicon-based semiconductor device 300 and the silicon substrate 210 excepting the first area (A) as shown in FIG. 9. In this way, the nitride-based semiconductor device 400 may be effectively insulated and isolated from the silicon-based semiconductor device 300. It should be noted that, in some embodiments, a plurality of the trenches (V) are formed via wet etching the first area (A) of the silicon substrate 210 when performing step c). In these embodiments, the insulating layer 220 is first patterned to form a plurality of sub-mask structures 2201 in the step c2) (see FIGS. 5 and 6). The sub-mask structures 2201 may form an array with each sub-mask structure 2201 having the same dimensions. Additionally, each two adjacent ones of the sub-mask structures 2201 may be spaced apart by the same amount. In this way, when performing the step c3) of wet etching the exposed first area (A) to form the plurality of trenches (V), the trenches (V) thus formed will have the same structure and the same dimensions, and the plurality of trenches (V) may be formed contiguously in the first area (A). This allows the nucleation layer 230 that is to be grown in the trenches (V) in a later step to have the flat surface and have a high quality. Referring to FIG. 5, in this embodiment, each of the sub-mask structures 2201 have a strip-like structure, the sub-mask structures 2201 are arranged in a one-dimensional array, have the same dimensions, and each two adjacent ones of the sub-mask-structures 2201 are spaced apart by the same amount. It should be noted that, the amount that each two adjacent ones of the sub-mask structures 2201 are spaced apart by is related to the total area of the trench surfaces of the trenches (V) subsequently formed. When the amount that the sub-masks are spaced apart by is increased, the total area of the trench surfaces of the trenches (V) is also increased. This relation also holds true in the reverse situation. Referring to FIG. 5, in some embodiments, when patterning the insulating layer 220, the first area (A) of the silicon substrate 210 may be exposed via a photolithography process. Referring to FIG. 6, in some embodiments, where a plurality of trenches (V) are formed, the trenches (V) are formed contiguously in the first area (A), and each of two adjacent ones of the trenches (V) will be connected together to form a W shape. In this way, the trench surfaces of the trenches (V) form a contiguous (111) orientation surface, and a high quality nucleation layer 230 may be subsequently grown on the first area (A) of the silicon substrate 210. A nucleation layer 230 thus grown would have less defects. Referring to FIGS. 6 and 7, in some embodiments, the silicon substrate 210 is formed with a plurality of trenches (V). The sub-mask structures 2201 of the insulating layer 220 each has a minimum width-length dimension (L), each of the trenches (V) has the trench depth (h) and the opening that has the width (c). In this embodiment, L=2h. This is because the trenches (V) are formed via a wet etching process that is isometric, and the trench depth (h) that is etched away is substantially equal to half the minimum width-length dimension (L) of the covering portion of the insulating layer 220. The trench surface of each of the trenches (V) is inclined with respect to a horizontal reference plane at an inclined angle (α). In some embodiments, c/h=1/(2 tan(α)), and the inclined angle (α) ranges from 54.5° to 54.9°. In some embodiments, if the insulating layer 220 is used as a mask, the insulating layer 220 may be made of a dielectric material such as SiO, SIN, AlO, or SiOn etc. In some embodiments, the insulating layer 220 may be a metallic material such as tungsten (W), tungsten nitride (WN), titanium (Ti), or gold (Au).

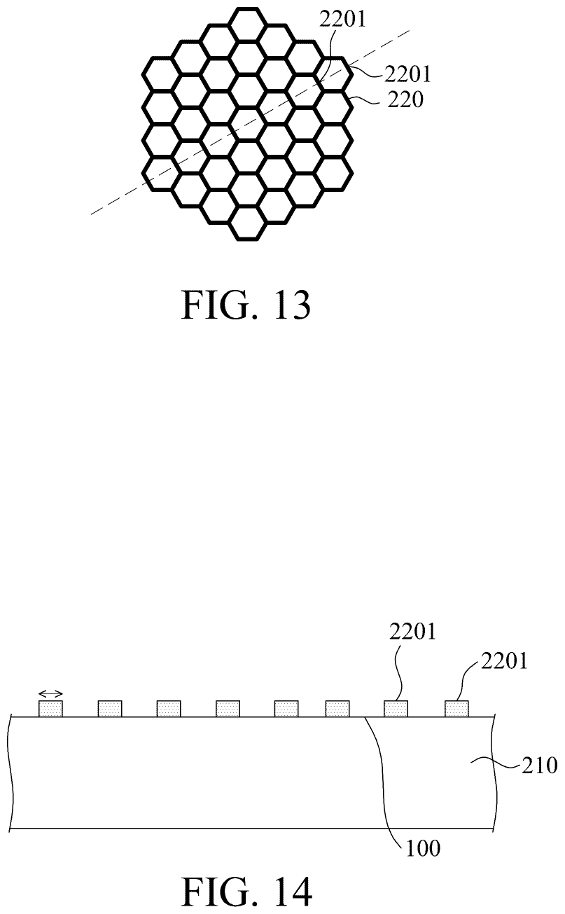

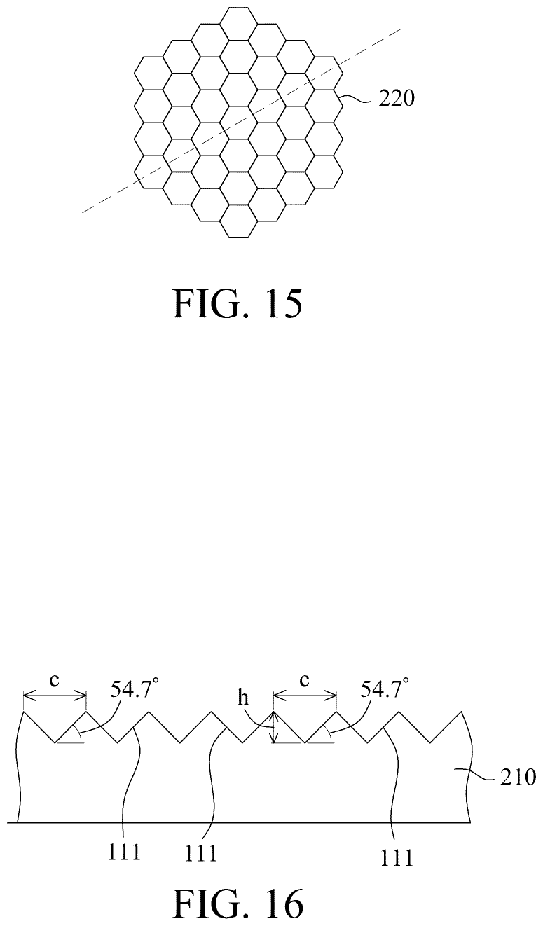

Referring to FIGS. 13 and 14, in some embodiments, in step c), the insulating layer 220 may be patterned directly via photolithography to form hexagonal patterns that partially expose the silicon substrate 210. Referring to FIGS. 15 and 16, in some embodiments, the silicon substrate 210 is formed with a plurality of trenches (V). The trenches (V) are formed contiguously in the first area (A), side walls of the trenches (V) are connected together to form a plurality of hexagonal shapes. It should be noted that these trenches (V) with the hexagonal shapes have (111) orientation surfaces which match the crystal lattice of the nucleation layer 230 and which is conducive for the growth of the nucleation layer 230. Additionally, by forming the hexagonal shapes from the side wall of the trenches (V), the surface area of the exposed silicon substrate 210 is increased which is conducive for epitaxially growing the nucleation layer 230. In this embodiment, in this embodiment, the inclined angle (α) is 54.7°.

The step d) of forming the nitride-based semiconductor device 400 may include steps d1) and d2). In the step d1), the nucleation layer 230 is epitaxially grown in the trench (V) to cover the trench (V) and form the flat surface. Since the trench surface of the trench (V) is with (111) orientation, and the nucleation layer 230 has good lattice matching characteristics with the (111) orientation of the trench surface, the nucleation layer 230 thus grown will be of a higher quality. It should be understood that, the thickness of the nucleation layer 230 is no less than the trench depth (h) of the trench (V), thereby allowing the nucleation layer 230 to cover the trench (V) and form the flat surface of the nucleation layer 230 that is parallel to a bottom surface of the silicon substrate 210. In the step d2), the nitride-based heterojunction 240 and the electrode structure are formed on the flat surface of the nucleation layer 230 to form the nitride-based semiconductor device 400. In this step d2), the heterojunction 240 has good lattice matching characteristics with the nucleation layer 230, and the heterojunction 240 thus obtained will be of a superior quality. The electrode structure is then formed on the heterojunction 240, and the nitride-based semiconductor device 400 is thus obtained.

In some embodiments, after performing the step d), the method of making the integrated semiconductor device further includes steps e) to h). In the step e), a passivation layer 260 is formed on the device preform to cover the silicon-based semiconductor device 300 and the nitride-based semiconductor device 400. The passivation layer 260 offers passivation and protection to the device preform as shown in FIG. 9, and increases moisture protection of the device preform.

Referring to FIG. 10, in the step f), the passivation layer 260 is planarized to form the flat upper surface. This improves reliability and continuity when laying metal wire circuitry on the passivation layer 260.

Referring to FIG. 11, in the step g), the passivation layer 260 is etched to form a first interconnecting hole unit 271 and a second interconnecting hole unit 272, each of which extends from the flat upper surface of the passivation layer 260 to respectively reach the nitride-based semiconductor device 400 and the silicon-based semiconductor device 300.

Referring to FIG. 12, in the step h), a first interconnecting metallic structure 281 and a second interconnecting metallic structure 282 are formed and are electrically connected to each other. The first interconnecting metallic structure 281 and the second interconnecting metallic structure 282 respectively extend into the first interconnecting hole unit 271 and the second interconnecting hole unit 272 to be electrically connected to the nitride-based semiconductor 400 and the silicon-based semiconductor 300, respectively. The first interconnecting metallic structure 281 and the second interconnecting metallic structure 282 are electrically and metallically connected to each other above the passivation layer 260 to electrically connect the silicon-based semiconductor layer 300 with the nitride-based semiconductor layer 400.

In some embodiments, the first interconnecting metallic structure 281 may be formed using electroplating techniques, and includes a first metallic via unit that is formed in the first interconnecting hole unit 271, and a first connecting unit that is located on the passivation layer 260 and that is metallically connected (electrically connected) to the first metallic via unit. The second interconnecting metallic structure 282 may be formed using electroplating techniques, and includes a second metallic via unit that is formed in the second interconnecting hole unit 272, and a second connecting unit that is located above the passivation layer 260 and that is metallically connected to the second metallic via unit. The first connecting unit of the first interconnecting metallic structure 281 may be metallically connected to second connecting unit of the second interconnecting metallic structure 282 above the passivation layer 260. It should be noted that interconnection between the nitride-based semiconductor device 400 and the silicon-based semiconductor device 300 may be arranged according to practical requirements. Referring to FIG. 12, in some embodiments, the drain electrode (D) of the electrode structure of the nitride-based semiconductor device 400 is electrically connected with the source electrode (S) of the silicon-based semiconductor device 300.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An integrated semiconductor structure comprising:
a silicon substrate having a first area and a second area, said first area being formed with a trench that has a trench surface with a (111) orientation, said second area having an area surface with a (100) orientation;
a silicon-based semiconductor device disposed on said area surface with the (100) orientation of said second area; and
a nitride-based semiconductor device disposed on said trench surface with the (111) orientation of said trench.

2. The integrated semiconductor structure as claimed in claim 1, wherein said nitride-based semiconductor device includes a nitride-based heterojunction.

3. The integrated semiconductor structure as claimed in claim 1, further comprising a protection layer covering said silicon-based semiconductor device and said nitride-based semiconductor device, and having a flat upper surface.

4. The integrated semiconductor structure as claimed in claim 3, further comprising:
a first interconnecting metallic structure that extends from said flat upper surface of said protection layer to said nitride-based semiconductor device to be electrically connected with said nitride-based semiconductor device; and
a second interconnecting metallic structure that extends from said flat upper surface of said protection layer to said silicon-based semiconductor device to be electrically connected with said silicon-based semiconductor device.

5. The integrated semiconductor structure as claimed in claim 3, wherein said protection layer includes:
an insulating layer covering said silicon-based semiconductor device and said silicon substrate excepting said first area; and
a passivation layer covering said insulating layer and said nitride-based semiconductor device.

6. The integrated semiconductor structure as claimed in claim 2, wherein:
said nitride-based semiconductor device further includes a nucleation layer and an electrode structure;
said nucleation layer is disposed in and fills said trench and is formed with a flat surface, said nitride-based heterojunction being disposed on said flat surface of said nucleation layer, and said electrode structure being disposed on said nitride-based heterojunction.

7. The integrated semiconductor structure as claimed in claim 1, wherein said silicon-based semiconductor device includes a semiconductor component or a circuit structure.

8. The integrated semiconductor structure as claimed in claim 1, wherein said integrated semiconductor structure includes a plurality of said trenches formed contiguously in said first area.

9. The integrated semiconductor structure as claimed in claim 1, wherein each of said trenches has a trench depth (h) and an opening that has a width (c), and said trench surface of each of said trenches is inclined with respect to a horizontal reference plane at an inclined angle (α), wherein c/h=1/(2 tan(α)), and said inclined angle (α) ranges from 54.5° to 54.9°.

10. The integrated semiconductor structure as claimed in claim 9, wherein said width (c) of said opening is 1.43 times said trench depth (h), and said inclined angle (α) is 54.7°

11. The integrated semiconductor structure as claimed in claim 9, wherein said trench depth (h) ranges from 20 nm to 100 nm.

12. The integrated semiconductor structure as claimed in claim 5, wherein said insulating layer is made of silicon oxide.

13. The integrated semiconductor structure as claimed in claim 5, wherein said passivation layer is made of one of silicon oxide, silicon nitride, aluminum oxide, and silicon oxynitride, or an organic insulating material.

14. The integrated semiconductor structure as claimed in claim 6, wherein a thickness of said nucleation layer is no less than a trench depth (h) of said trench.

15. The integrated semiconductor structure as claimed in claim 2, wherein said nitride-based heterojunction includes a buffer layer, a channel layer, and a barrier layer.

16. The integrated semiconductor structure as claimed in claim 15, wherein:
said channel layer is made of one of GaN and AlₓGa₁₋ₓN; and
said barrier layer is made of one of AlN, InN, AlₓGa₁₋ₓN, InₓAl₁₋ₓN, and InₓAl_{y}GaN.

17. A method for making an integrated semiconductor structure comprising:
a) providing a silicon substrate having a first area and a second area each having a area surface with a (100) orientation;
b) forming a silicon-based semiconductor device on the area surface with the (100) orientation of the second area;
c) wet etching the first area of the silicon substrate to form a trench having a trench surface with a (111) orientation; and
d) forming a nitride-based semiconductor device on the trench surface to create a device preform.

18. The method of making the integrated semiconductor device as claimed in claim 17, wherein the step c) of wet etching the first area includes:
c1) forming an insulating layer on the silicon substrate to cover the first area (A) and the silicon-based semiconductor device on the second area;
c2) patterning the insulating layer to expose the first area of the silicon substrate; and
c3) wet etching the exposed first area of the silicon substrate to form the trench (V) having the trench surface with the (111) orientation. 19. The method of making the integrated semiconductor device as claimed in claim 17, wherein the step d) of forming the nitride-based semiconductor device includes:
d1) epitaxially growing a nucleation layer in the trench to cover the trench (V) and form a flat surface; and
d2) forming a nitride-based heterojunction and an electrode structure on the flat surface of the nucleation layer to form the nitride-based semiconductor device.

20. The method of making the integrated semiconductor device as claimed in claim 17, further comprising, after the step d):
e) forming a passivation layer on the device preform that covers the silicon-based semiconductor device and the nitride-based semiconductor device;
f) planarizing the passivation layer to form a flat upper surface;
g) etching the passivation layer to form a first interconnecting hole unit and second interconnecting hole unit each of which extends from the flat upper surface of the passivation layer to respectively reach the nitride-based semiconductor device and the silicon-based semiconductor device;
h) forming a first interconnecting metallic structure and a second interconnecting metallic structure that are electrically connected to each other, the first interconnecting metallic structure and the second interconnecting metallic structure respectively extending into the first interconnecting hole and the second interconnecting hole to be electrically connected to the nitride-based semiconductor device and the silicon-based semiconductor device, respectively.
